(19) United States
(12) Patent Application Publication
(10) Pub. No.: US 2010/0187593 A1
(43) Pub. Date: Jul. 29, 2010

(54) NAND FLASH MEMORY AND METHOD FOR MANUFACTURING THE SAME

(75) Inventor: Mutsuo MORIKADO, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/691,140

(22) Filed: Jan. 21, 2010

(30) Foreign Application Priority Data
Jan. 27, 2009 (JP) 2009-15688

(51) Int. Cl. H01L 29/788; H01L 21/336

(52) U.S. Cl. 257/316; 438/261; 257/E29.3; 257/E21.409

(57) ABSTRACT

A memory cell of NAND flash memory has a floating gate electrode taking a pillared shape formed on the first element region via a gate insulation film; diffusion layers formed in regions located on both sides of the floating gate electrode in the first element region; an IPD film formed on a top face of the floating gate electrode so as to extend over side faces of the floating gate electrode in a second direction perpendicular to the first direction; and a control gate electrode formed on the floating gate electrode and between adjacent floating gate electrodes via the IPD film so as to be continuous in the second direction. The IPD film is a low-k film.

### CROSS-REFERENCE TO RELATED APPLICATION

This application is based upon and claims the benefit of priority from the prior Japanese Patent Application No. 2009-15688, filed on Jan. 27, 2009, the entire contents of which are incorporated herein by reference.

### BACKGROUND OF THE INVENTION

1. Field of the Invention

The present invention relates to a NAND flash memory including memory cells in each of which a control gate electrode is provided on each of both sides of a floating gate electrode via an IPD (Inter-poly dielectrics) film, and its manufacturing method.

2. Background Art

In recent years, size of the NAND flash memory has been shrunk.

If the size of the NAND flash memory is shrunk, then it becomes difficult to ensure the desired coupling ratio because of the effect of the parasitic capacitance in each memory cell of the NAND flash memory as represented by the following Expressions (1) to (3).

Here, relations among a capacitance Cox, a film thickness tox, and an area Sox of a tunnel oxide film of the memory cell are represented by Expression (1). By the way, ∈ is a dielectric constant of the tunnel oxide film.

Cox=∈Sox/tox (1)

Relations among a capacitance Cipd, a capacitance film thickness tipd (converted into SiO₂), and an area Sipd of an insulation film (IPD film) between adjacent polysilicons are represented by Expression (2).

Cipd=∈Sipd/tipd (2)

Therefore, a coupling ratio Cr is represented by Expression (3).

Cr=Cipd/(Cox+Cipd) (3)

In recent years, a NAND flash memory having a cell structure in which a control gate electrode CG is disposed on both sides of a floating gate electrode FG has been proposed (see, for example, Japanese Patent Laid-Open No. 2007-294595).

When the distance between adjacent floating gate electrodes of the conventional NAND flash memory is shrunk, it is necessary to keep the coupling ratio Cr which becomes an efficiency factor in writing represented by Expression (3) at a predetermined value or more in order to obtain desired characteristics of the memory cell.

In addition, it is necessary to keep the film thickness of the control gate electrode formed by a conductive layer such as polysilicon or metal at an electrically effective film thickness or more.

If the distance between adjacent floating gate electrodes is shrunk, therefore, it becomes difficult to form the control gate electrode and the IPD film in a gap between the adjacent floating gate electrodes.

On the other hand, it is demanded to make the IPD film thin according to shrink the size of the NAND flash memory. If the IPD film is made thin, it becomes difficult to satisfy specifications of the leak current of the IPD film and in addition, it becomes difficult to ensure the operation margin of the memory cell.

Therefore, it is considered that making the IPD film thin is an important factor to shrink the size of the memory cell.

In this way, a problem to shrink the size of the memory cell in the NAND flash memory is how the size between adjacent floating gate electrodes is shrunk.

In the conventional art, for example, the area of the floating gate electrode is made larger than that of the tunnel insulation film by covering each side face of the floating gate electrode with the IPD film in order to ensure the coupling ratio Cr of the memory cell. The IPD film is formed by, for example, a high dielectric constant film (ONO film) composed of three layers SiO₂—SiN—SiO₂.

Therefore, the IPD film used in the conventional art as well is a film which is physically thick, but thin in EOT (Equivalent Oxide Thickness).

For shrinking the size between adjacent floating gate electrodes, however, the IPD film must be made thin.

In other words, the configuration of the conventional NAND flash memory has a problem that it is difficult to shrink the size of the memory cell.

### SUMMARY OF THE INVENTION

According to one aspect of the present invention, there is provided: a NAND flash memory comprising:

a first selection gate transistor formed on a first element region of a semiconductor substrate and connected to a bit line at first end thereof, a plurality of element regions and a plurality of element isolation regions being formed in the semiconductor substrate by a line and space pattern extending in a first direction, the first element region being included in the element regions;

a second selection gate transistor formed on the first element region of the semiconductor substrate and connected to a source line at first end thereof; and

a plurality of memory cells formed on the first element region of the semiconductor substrate and connected in series between a second end of the first selection gate transistor and a second end of the second selection gate transistor,

wherein each of the memory cells comprises:

a floating gate electrode taking a pillared shape formed on the first element region via a gate insulation film;

diffusion layers formed in regions located on both sides of the floating gate electrode in the first element region;

an IPD film formed on a top face of the floating gate electrode so as to extend over side faces of the floating gate electrode in a second direction perpendicular to the first direction; and

a control gate electrode formed on the floating gate electrode and between adjacent floating gate electrodes via the IPD film so as to be continuous in the second direction, and

the IPD film is a low-k film.

According to another aspect of the present invention, there is provided: a NAND flash memory comprising:

a first selection gate transistor formed on a first element region of a semiconductor substrate and connected to a bit line at first end thereof, a plurality of element regions and a plurality of element isolation regions being formed in the semiconductor substrate by a line and space pattern extending in a first direction, the first element region being included in the element regions;

a second selection gate transistor formed on the first element region of the semiconductor substrate and connected to a source line at first end thereof; and

a plurality of memory cells formed on the first element region of the semiconductor substrate and connected in series between a second end of the first selection gate transistor and a second end of the second selection gate transistor,

wherein each of the memory cells comprises:

a floating gate electrode taking a pillared shape formed on the first element region via a gate insulation film;

diffusion layers formed in regions located on both sides of the floating gate electrode in the first element region;

an air gap formed on a top face of the floating gate electrode so as to extend over side faces of the floating gate electrode in a second direction perpendicular to the first direction; and

a control gate electrode formed on the floating gate electrode and between adjacent floating gate electrodes via the air gap so as to be continuous in the second direction.

According to still another one aspect of the present invention, there is provided: a NAND flash memory manufacturing method comprising:

forming a gate insulation film on a semiconductor substrate;

forming a first conductor film on the gate insulation film;

etching the gate insulation film, the first conductor film and the semiconductor substrate by using a first resist pattern as a mask, and thereby forming a first trench extending in a first direction;

forming an element isolating insulation film in the first trench so as to cause a position of a top face of the element isolating insulation film to become lower than a position of a top face of the first conductor film and become higher than a position of a bottom face of the first conductor film;

depositing an insulation film on the first conductor film and the element isolating insulation film;

depositing a second conductor film on the insulation film;

etching the second conductor film, the insulation film and the first conductor film by using a second resist pattern as a mask, and thereby forming a second trench extending in a second direction perpendicular to the first direction and linking to the semiconductor substrate;

removing the insulation film; and

forming an interlayer insulation film in the second trench.

### BRIEF DESCRIPTION OF THE DRAWINGS

FIG. 1 is a plan view of a schematic pattern near a memory cell array of a NAND flash memory 100 according to a first embodiment which is one aspect of the present invention;

FIG. 2 is a sectional view of a section of the NAND flash memory 100 shown in FIG. 1 taken along an X-X line;

FIG. 3 is a sectional view of a section of the NAND flash memory 100 shown in FIG. 1 taken along a Y-Y line;

FIG. 4 is a sectional view showing the section of the memory cell array taken along an X-X line in processes of the manufacturing method of the NAND flash memory according to the first embodiment shown in FIG. 1;

FIG. 5 is a sectional view showing the section of the memory cell array taken along an X-X line in a process subsequent to that shown in FIG. 4 in the manufacturing method of the NAND flash memory 100 shown in FIG. 1;

FIG. 6 is a sectional view showing the section of the memory cell array taken along an X-X line in a process subsequent to that shown in FIG. 5 in the manufacturing method of the NAND flash memory 100 shown in FIG. 1;

FIG. 7 is a sectional view showing the section of the memory cell array taken along an X-X line in a process subsequent to that shown in FIG. 6 in the manufacturing method of the NAND flash memory 100 shown in FIG. 1;

FIG. 8 is a sectional view showing the section of the memory cell array taken along an X-X line in a process subsequent to that shown in FIG. 7 in the manufacturing method of the NAND flash memory 100 shown in FIG. 1;

FIG. 9 is a sectional view showing the section of the memory cell array taken along an X-X line in a process subsequent to that shown in FIG. 8 in the manufacturing method of the NAND flash memory 100 shown in FIG. 1;

FIG. 10 is a sectional view showing the section of the memory cell array taken along an X-X line in a process subsequent to that shown in FIG. 9 in the manufacturing method of the NAND flash memory 100 shown in FIG. 1;

FIG. 11 is a sectional view showing the section of the memory cell array taken along an X-X line in a process subsequent to that shown in FIG. 10 in the manufacturing method of the NAND flash memory 100 shown in FIG. 1;

FIG. 12 is a sectional view showing the section of the memory cell array taken along an X-X line in a process subsequent to that shown in FIG. 11 in the manufacturing method of the NAND flash memory 100 shown in FIG. 1;

FIG. 13 is a sectional view showing the section of the memory cell array taken along an X-X line in a process subsequent to that shown in FIG. 12 in the manufacturing method of the NAND flash memory 100 shown in FIG. 1;

FIG. 14 is a sectional view showing a section of the memory cell array taken along a Y-Y line in the same process as that in FIG. 10 in the manufacturing method of the NAND flash memory 100 shown in FIG. 1;

FIG. 15 is a sectional view showing a section of the memory cell array taken along a Y-Y line in a process subsequent to that shown in FIG. 14 in the manufacturing method of the NAND flash memory 100 shown in FIG. 1;

FIG. 16 is a sectional view showing a section of the memory cell array taken along a Y-Y line in a process subsequent to that shown in FIG. 15 in the manufacturing method of the NAND flash memory 100 shown in FIG. 1;

FIG. 17 is a sectional view showing a section of the memory cell array taken along a Y-Y line in a process subsequent to that shown in FIG. 16 in the manufacturing method of the NAND flash memory 100 shown in FIG. 1;

FIG. 18 is a sectional view showing a section of the NAND flash memory 100 according to the first embodiment taken along the word line paying attention to the space between adjacent floating gate electrodes;

FIG. 19 is a sectional view showing a section of the conventional NAND flash memory taken along the word line paying attention to the space between adjacent floating gate electrodes;

FIG. 20 is a diagram showing relations between an electric field applied to the low-k film, the ONO film and the silicon oxide film having the same film thickness and their leak currents;

FIG. 21 is a plan view of a schematic pattern near a memory cell array of a NAND flash memory 100 according to the second embodiment which is one aspect of the present invention;

FIG. 22 is a sectional view of a section of the NAND flash memory 100 shown in FIG. 21 taken along an X-X line;

FIG. 23 is a sectional view of a section of the NAND flash memory 100 shown in FIG. 21 taken along a Y-Y line;

FIG. 24 is a sectional view showing the section of the memory cell array taken along an X-X line in a process of the manufacturing method of the NAND flash memory according to the second embodiment shown in FIG. 1;

FIG. 25 is a sectional view showing the section of the memory cell array taken along an X-X line in a process subsequent to that shown in FIG. 24 in processes of the manufacturing method of the NAND flash memory according to the second embodiment shown in FIG. 1;

FIG. 26 is a sectional view showing the section of the memory cell array taken along an X-X line in a process subsequent to that shown in FIG. 25 in processes of the manufacturing method of the NAND flash memory according to the second embodiment shown in FIG. 1;

FIG. 27 is a sectional view showing the section of the memory cell array taken along an X-X line in a process subsequent to that shown in FIG. 26 in processes of the manufacturing method of the NAND flash memory according to the second embodiment shown in FIG. 1;

FIG. 28 is a sectional view showing the section of the memory cell array taken along an X-X line in a process subsequent to that shown in FIG. 27 in processes of the manufacturing method of the NAND flash memory according to the second embodiment shown in FIG. 1;

FIG. 29 is a sectional view showing the section of the memory cell array taken along an X-X line in a process subsequent to that shown in FIG. 28 in processes of the manufacturing method of the NAND flash memory according to the second embodiment shown in FIG. 1;

FIG. 30 is a sectional view showing the section of the memory cell array taken along an X-X line in a process subsequent to that shown in FIG. 29 in processes of the manufacturing method of the NAND flash memory according to the second embodiment shown in FIG. 1;

FIG. 31 is a sectional view showing a section of the memory cell array taken along a Y-Y line in the same process as that in FIG. 27 in the manufacturing method of the NAND flash memory 100 shown in FIG. 1;

FIG. 32A is a sectional view showing a section of the memory cell array taken along a Y-Y line in a process subsequent to that shown in FIG. 31 in the manufacturing method of the NAND flash memory 100 shown in FIG. 1;

FIG. 32B is a sectional view showing a section of the memory cell array taken along a Y-Y line in a process subsequent to that shown in FIG. 32A in the manufacturing method of the NAND flash memory 100 shown in FIG. 1;

FIG. 33 is a sectional view showing a section of the memory cell array taken along a Y-Y line in a process subsequent to that shown in FIG. 32B in the manufacturing method of the NAND flash memory 100 shown in FIG. 1;

FIG. 34 is a sectional view showing a section of the memory cell array taken along a Y-Y line in a process subsequent to that shown in FIG. 33 in the manufacturing method of the NAND flash memory 100 shown in FIG. 1; and

FIG. 35 is a sectional view showing a section of the memory cell array taken along a Y-Y line in a process subsequent to that shown in FIG. 34 in the manufacturing method of the NAND flash memory 100 shown in FIG. 1.

### DETAILED DESCRIPTION

According to the present invention, for example, a low k film or an air gap having a further low dielectric constant is used as the IPD film of the NAND flash memory.

As a result, an IPD film which is physically thin and which has a thick equivalent oxide thickness is obtained.

Therefore, it is possible to make the IPD film between adjacent floating gate electrodes thin and shrink the size between the floating gate electrodes.

In other words, it becomes possible to further shrink the size of the memory cell of the NAND flash memory.

Hereafter, embodiments of a NAND flash memory according to the present invention will be described more specifically with reference to the drawings.

### First Embodiment

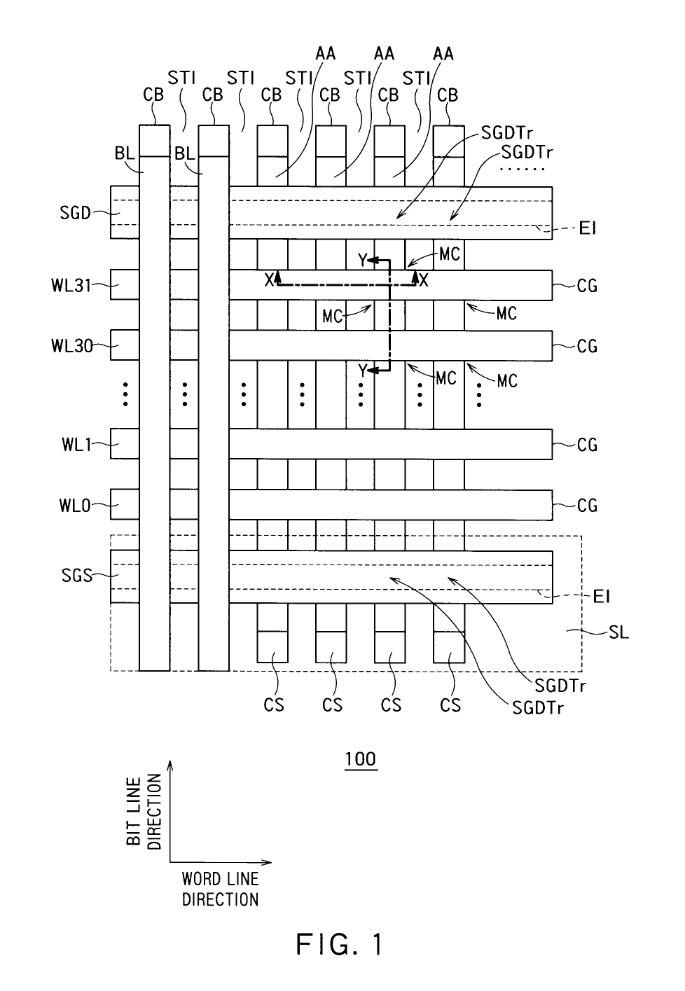

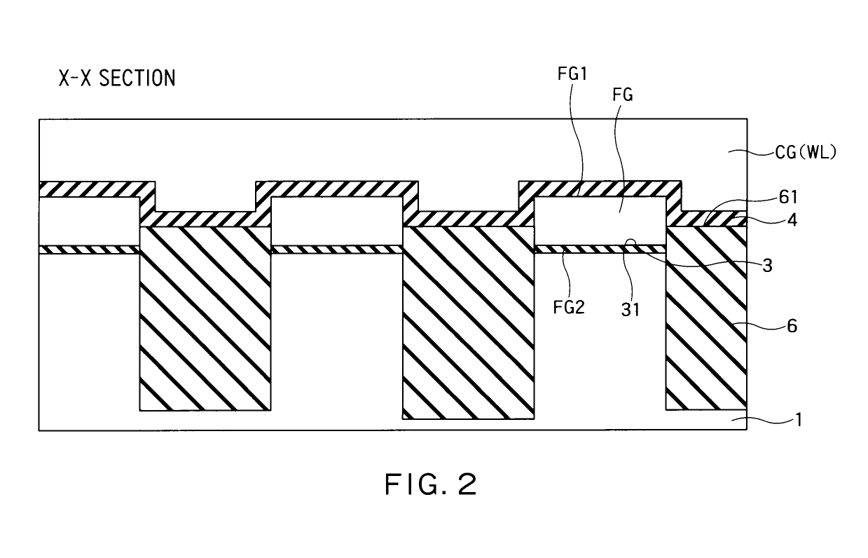

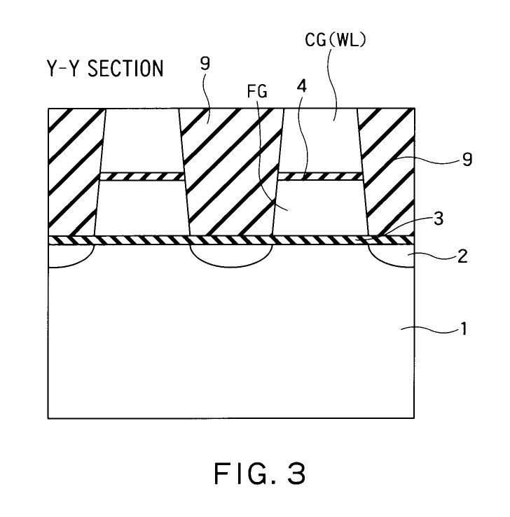

FIG. 1 is a plan view of a schematic pattern near a memory cell array of a NAND flash memory 100 according to a first embodiment which is one aspect of the present invention. FIG. 2 is a sectional view of a section of the NAND flash memory 100 shown in FIG. 1 taken along an X-X line. FIG. 3 is a sectional view of a section of the NAND flash memory 100 shown in FIG. 1 taken along a Y-Y line.

As shown in FIGS. 1, 2 and 3, element regions AA and element isolation regions (STI: Shallow Trench Isolation) which extend in the longitudinal direction in FIGS. 1, 2 and 3 are formed on a silicon substrate 1, which is a semiconductor substrate, in a memory cell region of the NAND flash memory cell 100 by a line & space pattern extending in a first direction (bit line BL direction).

The NAND flash memory cell 100 includes selection gate transistors SGDTr and SGSTr, and memory cells MC.

The selection gate transistor SGDTr is formed on the element region AA, and connected to bit line BL at first end (drain).

The selection gate transistor SGSTr is formed on the element region AA, and connected to source line at first end (source).

Control gate electrodes CG and selection gate electrodes SGD and SGS are formed in the NAND flash memory 100 so as to extend in a second direction (word line WL direction) and so as to be arranged at predetermined intervals in the first direction (bit line BL direction). For example, two selection gate electrodes (SGD and SGS) are formed every thirty-two control gate electrodes CG (word lines WL).

The selection gate electrode SGD constitutes a selection gate transistor SGDTr in conjunction with diffusion layers formed on the element region AA and a gate insulation film 3.

The selection gate electrode SGS constitutes a selection gate transistor SGSTr in conjunction with diffusion layers formed on the element region AA and a gate insulation film 3.

Memory cells MC are formed on the element region AA. A plurality of memory cells MC is connected in series between a second end (source) of a selection gate transistor SGDTr and a second end (drain) of a selection gate transistor SGSTr.

The memory cell MC includes diffusion layers 2, the gate insulation film (tunnel oxide film) 3, a floating gate electrode FG, an IPD film 4, and the control gate electrode CG (word line WL).

The diffusion layers 2 are formed in regions which are included in the element region AA and located on both sides of the floating gate electrode FG. In other words, it can be said that a memory cell string is constituted by arranging a plurality of memory cells MC at predetermined intervals in the first direction so as to share the diffusion layer 2 between adjacent memory cells MC and the memory cell strings are arranged at predetermined intervals in the second direction.

The floating gate electrode FG takes a pillared shape formed on the element region AA via the gate insulation film 3.

The IPD film 4 is formed on the top face of the floating gate electrode FG so as to extend over side faces of the floating gate electrode FG in the second direction (word line direction) perpendicular to the first direction (bit line direction). The IPD film 4 is formed on the element isolating insulation film 6 as well continuously.

The control gate electrode CG is formed on the floating gate electrode FG and between adjacent floating gate electrodes FG via the IPD film 4 so as to be continuous in the second direction (word line direction). As a result, the coupling ratio of the memory cell MC already described can be increased.

In this way, the control gate electrode CG is formed so as to extend over adjacent element regions AA (i.e., so as to stride across the element isolating insulation film 6 in the element isolation region). The IPD film 4 is formed between the control gate electrode CG and the element isolating insulation film 6 as well.

The IPD film 4 is a low-k film, such as a porous SiO₂ film or a SiCOH film, having a dielectric constant ∈=approximately 2.5 (hereafter, the IPD film 4 is referred to as low-k film 4 as well). An air gap having ∈=1.0 can be applied to the IPD film 4 instead of the low-k film.

A top face 61 of the element isolating insulation film 6 is set so as to be higher in position than a top face 31 of the gate insulation film 3. In other words, the position of the top face 61 of the element isolating insulation film 6 is set so as to become lower than that of a top face FG1 of the floating gate electrode FG and become higher than that of a bottom face FG2 of the floating gate electrode FG.

A bit line contact CB is connected between a bit line BL and the element region AA (drain of a transistor of a selection gate electrode SGD).

A source line contact CS is connected between a source line SL and the element region AA (source of a transistor of a selection gate electrode SGS).

The control gate electrodes CG, the IPD films 4, and the floating gate electrodes FG of memory cells MC adjacent in the first direction are isolated from each other by an interlayer insulation film 9.

A manufacturing method of the NAND flash memory 100 according to the first embodiment having the configuration described heretofore will now be described.

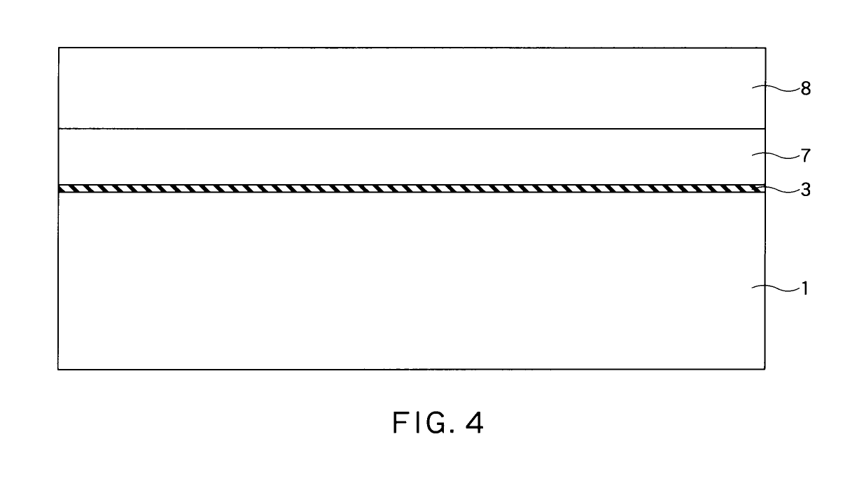

FIGS. 4 to 13 are sectional views showing the section of the memory cell array taken along an X-X line in processes of the manufacturing method of the NAND flash memory according to the first embodiment shown in FIG. 1.

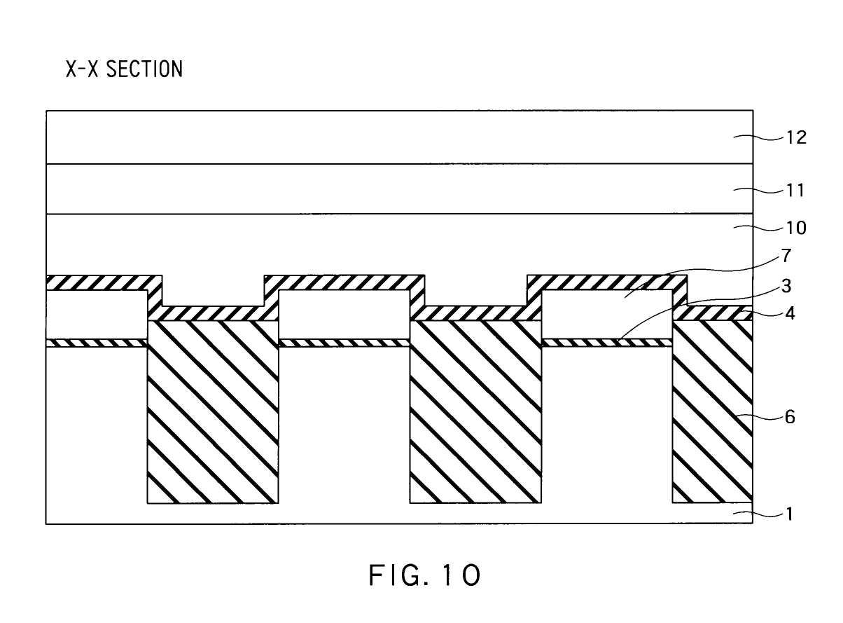

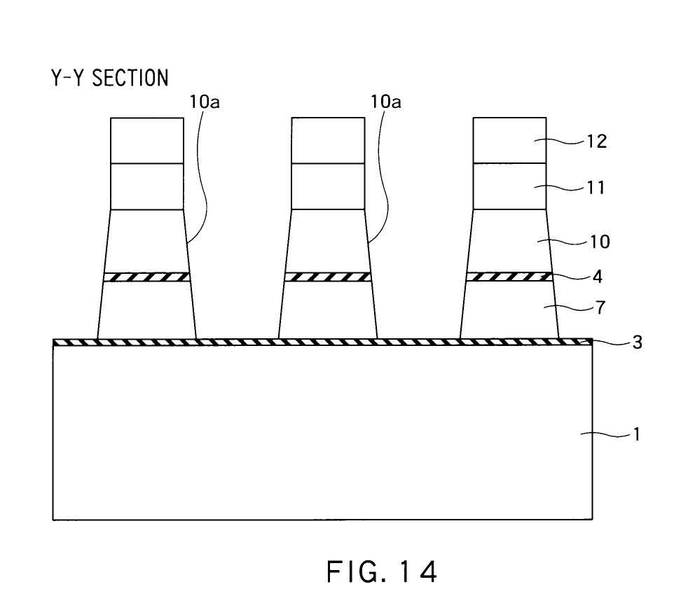

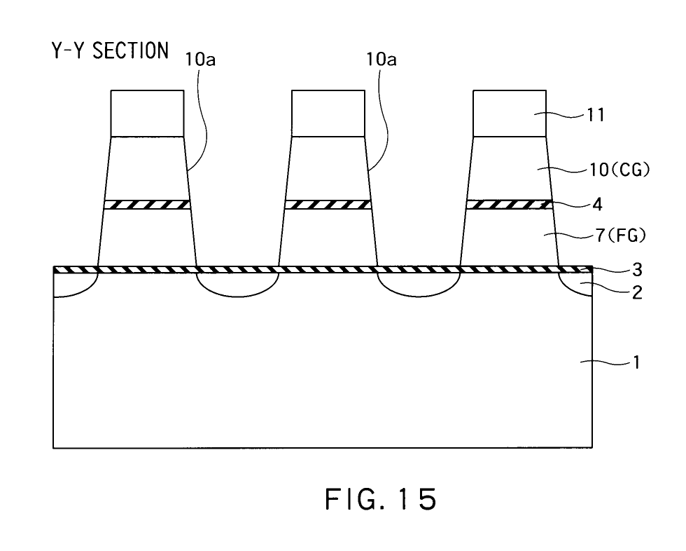

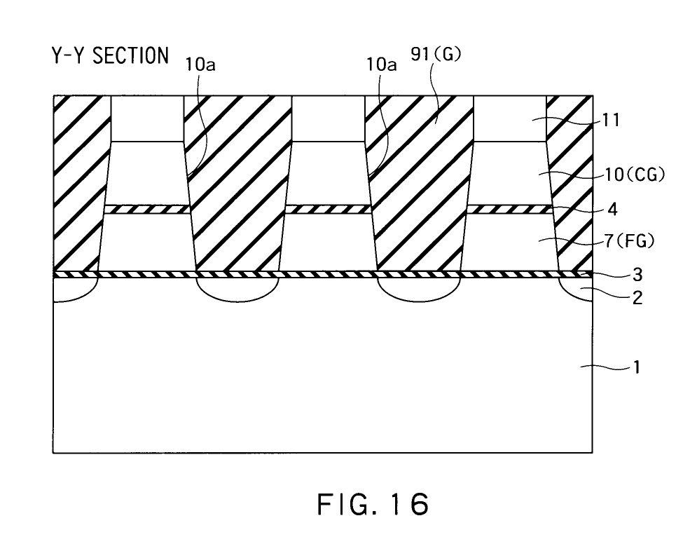

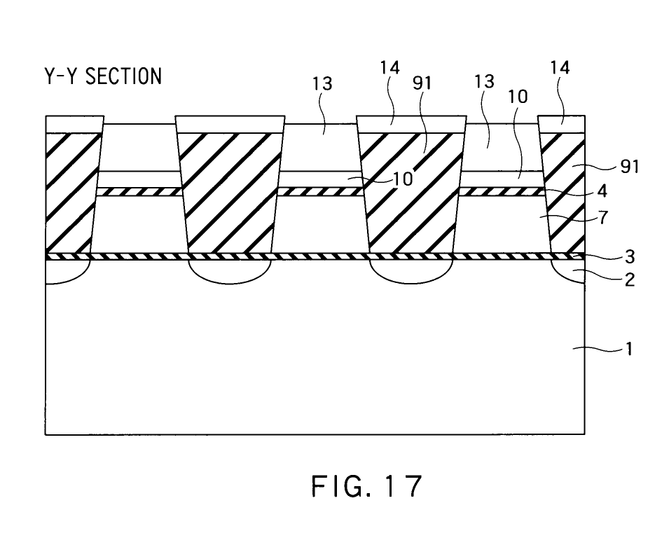

FIG. 14 is a sectional view showing a section of the memory cell array taken along a Y-Y line in the same process as that in FIG. 10 in the manufacturing method of the NAND flash memory 100 shown in FIG. 1. FIG. 15 is a sectional view showing a section of the memory cell array taken along a Y-Y line in a process subsequent to that shown in FIG. 14 in the manufacturing method of the NAND flash memory 100 shown in FIG. 1. FIG. 16 is a sectional view showing a section of the memory cell array taken along a Y-Y line in a process subsequent to that shown in FIG. 15 in the manufacturing method of the NAND flash memory 100 shown in FIG. 1. FIG. 17 is a sectional view showing a section of the memory cell array taken along a Y-Y line in a process subsequent to that shown in FIG. 16 in the manufacturing method of the NAND flash memory 100 shown in FIG. 1.

First, a well/channel is formed by conducting doping on the silicon substrate 1.

In addition, a thermal oxide film (SiO₂) which becomes the gate insulation film 3 is formed on the silicon substrate 1. A film thickness of the thermal oxide film in a region where a high voltage to be used at the time of programming/erasing is applied is, for example, approximately 35 nm. On the other hand, a film thickness of the thermal oxide film in a region where the high voltage is not applied is, for example, approximately 8 nm.

A polysilicon serving as a conductor film which becomes the floating gate electrode FG is deposited so as to have a thickness of, for example, approximately 80 nm. As a result, a polysilicon film 7 is formed on the thermal oxide film 3.

In addition, a SiN film 8 is deposited on the whole face of the polysilicon film 7 so as to have a thickness of, for example, approximately 100 nm (FIG. 4). The SiN film 8 serves as a stopper film in CMP (Chemical Mechanical Polishing) described later.

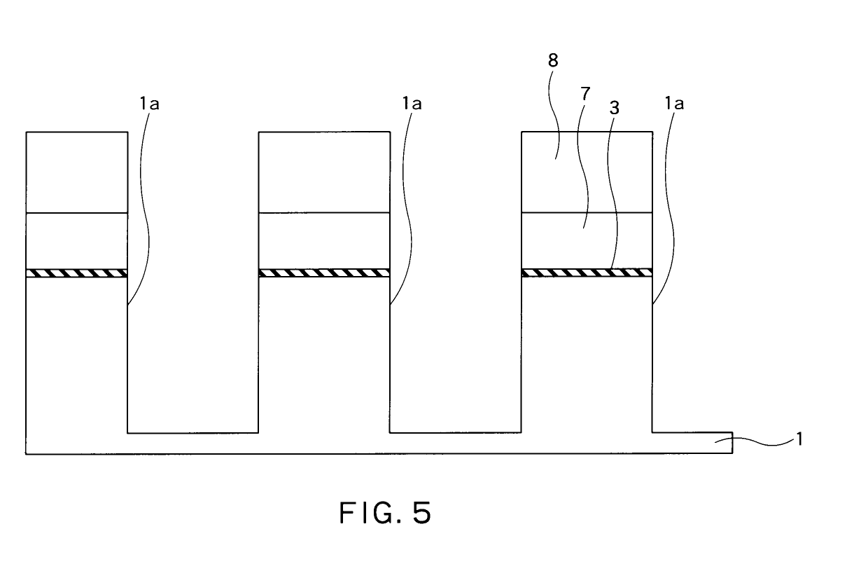

A desired resist pattern (not illustrated) for forming the element region AA is formed on the SiN film 8. A trench 1a extending in the bit line direction and having a desired depth (for example, 200 nm) is formed by successively etching the SiN film 8, the polysilicon film 7, the gate insulation film 3, and the silicon substrate 1 by using the resist pattern as a mask and using the RIE method. Then, the resist pattern remaining on the silicon substrate 1 is removed (FIG. 5).

A TEOS (Tetraethyl Orthosilicate) film is deposited so as to have a thickness of approximately 400 nm by using the CVD method. As a result, the trench 1a formed in the silicon substrate 1 is buried with SiO₂ until the SiN film 8 is embedded.

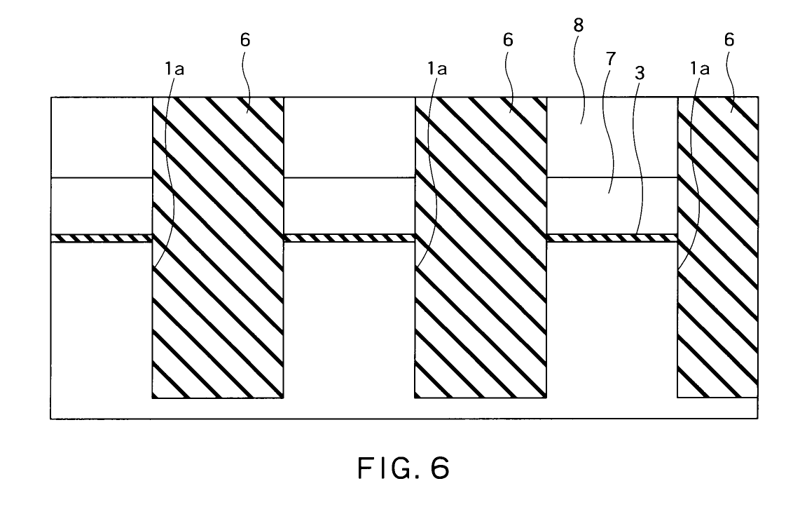

Then, planarization is conducted by using the SiN film 8 as a stopper and the CMP method so as to expose the SiN film 8 remaining on the silicon substrate 1. As a result, the element isolating insulation film 6 which becomes the STI (Shallow Trench Isolation) is formed (FIG. 6).

After the element isolating insulation film 6 is formed, the SiO₂ film embedded in the trench is etched and removed until a part of each of side faces of the polysilicon film 7 is exposed by using the remaining SiN film 8 as a mask and using the RIE (Reactive Ion Etching) method.

As a result, the position of the top face 61 of the element isolating insulation film 6 becomes lower than that of a top face 71 of the polysilicon film 7 (i.e., the floating gate electrode FG) and becomes higher than that of a bottom face 72 of the polysilicon film 7.

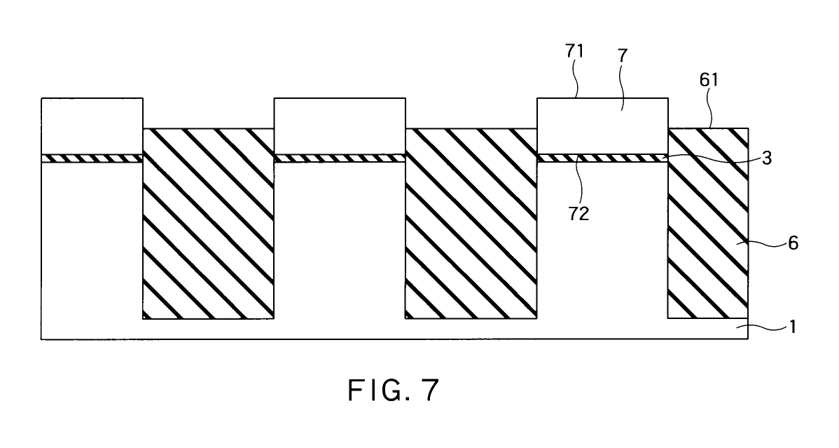

In addition, the remaining SiN film 8 is removed by using a chemical such as, for example, a H₃PO₄ (FIG. 7) solution.

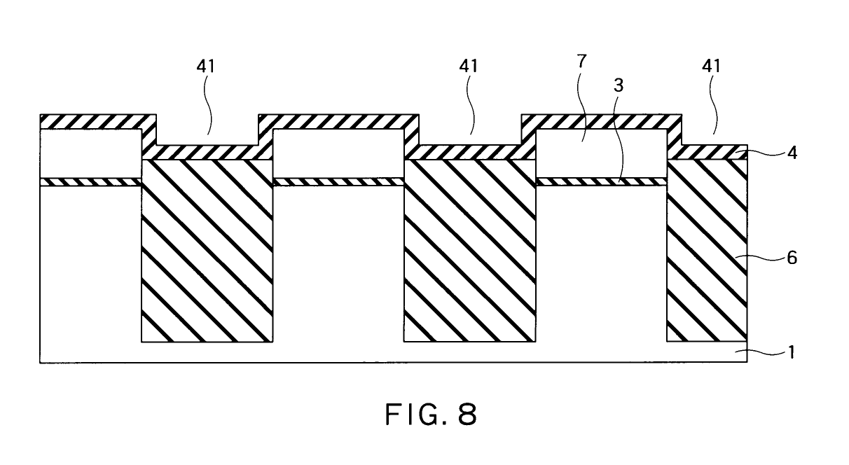

A low-k film (here, for example, a porous SiO₂ film, SiCOH, or the like having a dielectric constant ∈=approximately 2.5) 4 is deposited over the silicon substrate 1 (on the polysilicon film 7 and the element isolating insulation film 6) so as to have a thickness of, for example, approximately 5 nm. As a result, the low-k film is formed on the surface of the polysilicon film 7 (the floating gate electrode FG) and on the surface of the element isolating insulation film 6 (FIG. 8).

As a result, the space between the floating gate electrodes FG adjacent in the word line direction is filled with the low-k film 4 so as to have a thickness of approximately 10 nm.

Here, the physical film thickness of the low-k film 4 becomes thinner than the physical film thickness of the high dielectric constant film used in the conventional NAND flash memory already described.

In this process, therefore, a space 41 between the floating gate electrodes FG adjacent in the word line direction in which the low-k film 4 is formed can be wider as compared with the conventional NAND flash memory.

a polysilicon film is deposited so as to have a thickness of approximately 120 nm on the low-k film 4 and in the space 41 between the adjacent floating gate electrodes FG in which the low-k film 4 is formed.

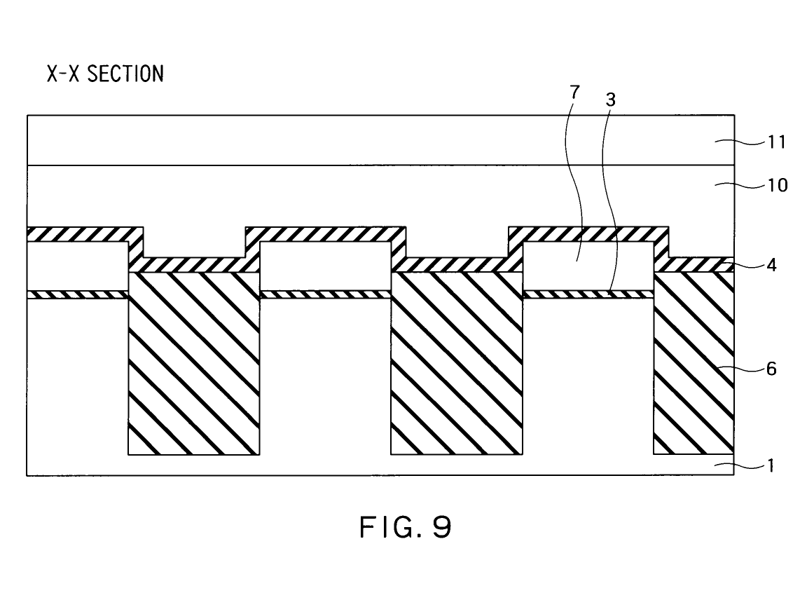

As a result, a polysilicon film 10 which becomes the control gate electrode CG is formed on the surface of the low-k film 4. In addition, a SiN film 11 which becomes a stopper film for CMP later is deposited on the polysilicon film 10 so as to have a thickness of, for example, approximately 100 nm (FIG. 9).

The SiN film 11, the polysilicon film 10, the low-k film 4, and the polysilicon film 7 are etched and selectively removed by using a resist pattern 12 for forming the control gate Electrode CG as a mask (FIGS. 10 and 14). As a result, the control gate Electrode CG is formed, and a trench 10a extending in the word line direction is formed.

After the remaining resist pattern 12 is removed, an HTO (High Temperature Oxide) film (not illustrated) having a thickness of, for example, approximately 3 nm is deposited on the whole face of the silicon substrate 1 as a silicon oxide film. As a result, exposed surfaces of the floating gate electrode FG and the control gate electrode CG are covered by the silicon oxide film (not illustrated).

For example, ions of As or the like are implanted into the silicon substrate 1 via the gate insulation film 3 as impurities. In addition, the impurities are activated by using the RTA (Rapid Thermal Anneal) method. As a result, the diffusion layers 2 are formed in the silicon substrate 1 (FIG. 15).

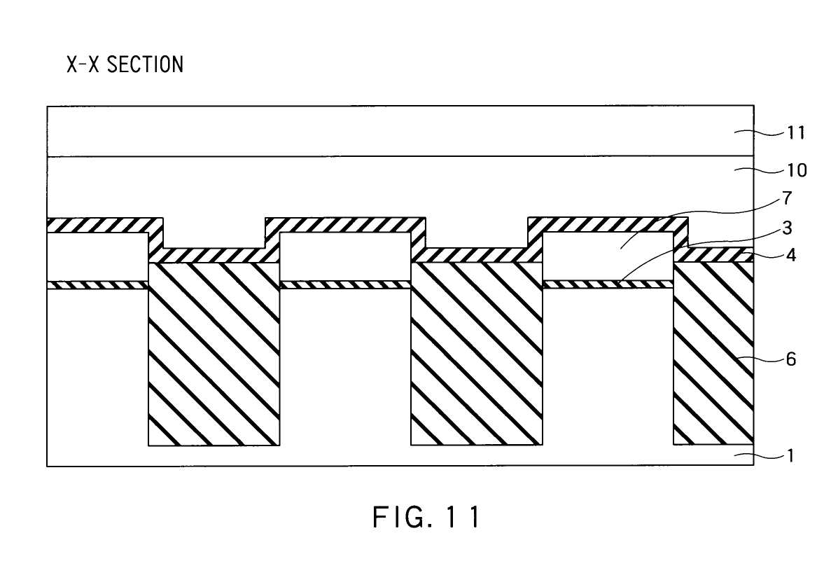

A BPSG (Boro-Phospho Silicate glass) film 91 is deposited over the whole face of the silicon substrate 1 so as to have a thickness of, for example, 500 nm. Heat treatment (for example, 850° C. and 10 minutes) is conducted on the BPSG film 91 by using an oxidation method of a steam atmosphere. The BPSG film 91 is planarized until the SiN film 11 is exposed by the CMP method (FIGS. 11 and 16).

As a result, an interlayer insulation film 9 (FIG. 3) which conducts insulation between the floating gate electrodes FG adjacent in the bit line direction (Y-Y direction) and between control gate electrodes adjacent in the bit line direction (Y-Y direction) is formed in the trench 10a.

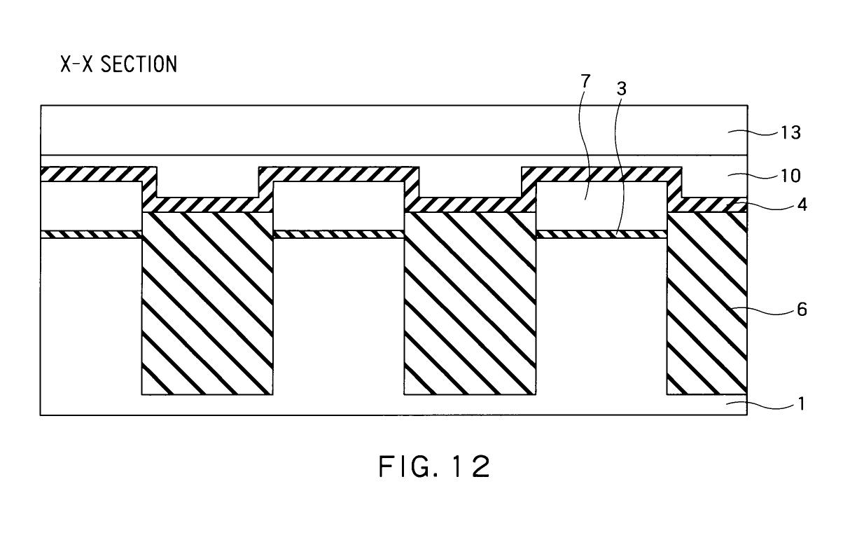

The exposed SiN film 11 is selectively removed by using, for example, the RIE method. For example, a Co film 14 is deposited on the polysilicon film 10 and the BPSG film 91. An upper part of the polysilicon film 10 is silicided by heat treatment required to form silicide. In other words, a silicide layer 13 is formed on the polysilicon film 10 (FIGS. 12 and 17). As a result, the control gate electrode CG is lowered in resistance. Then, the Co film 14 which dose not react is removed.

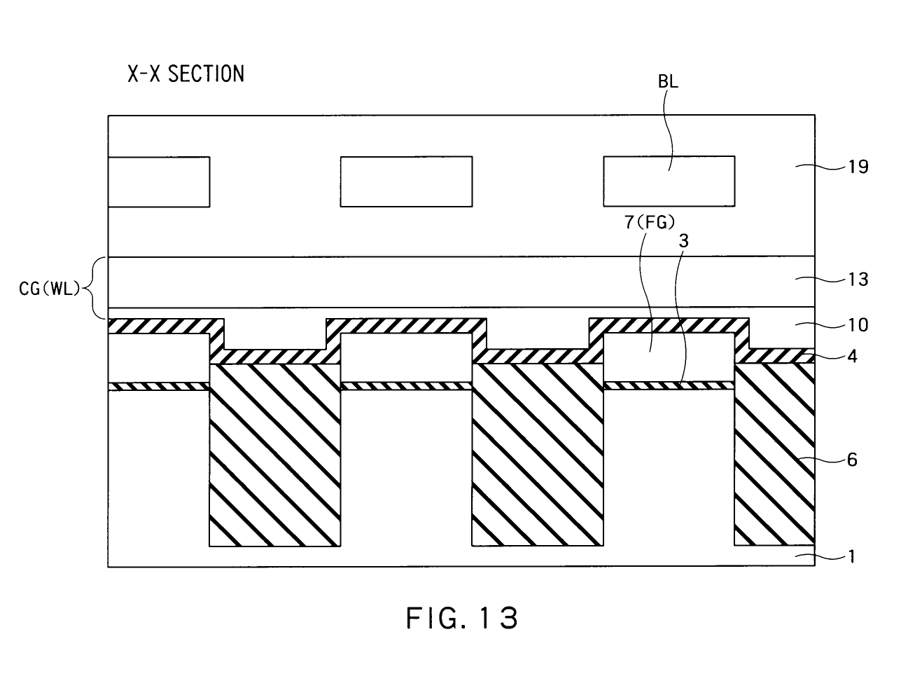

An interconnections such as an interlayer insulation film 19 and BL lines are formed on the silicon substrate 1 by a typical manufacturing process of the NAND flash memory (FIG. 13). As a result, the NAND flash memory 100 shown in FIGS. 1, 2 and 3 is completed.

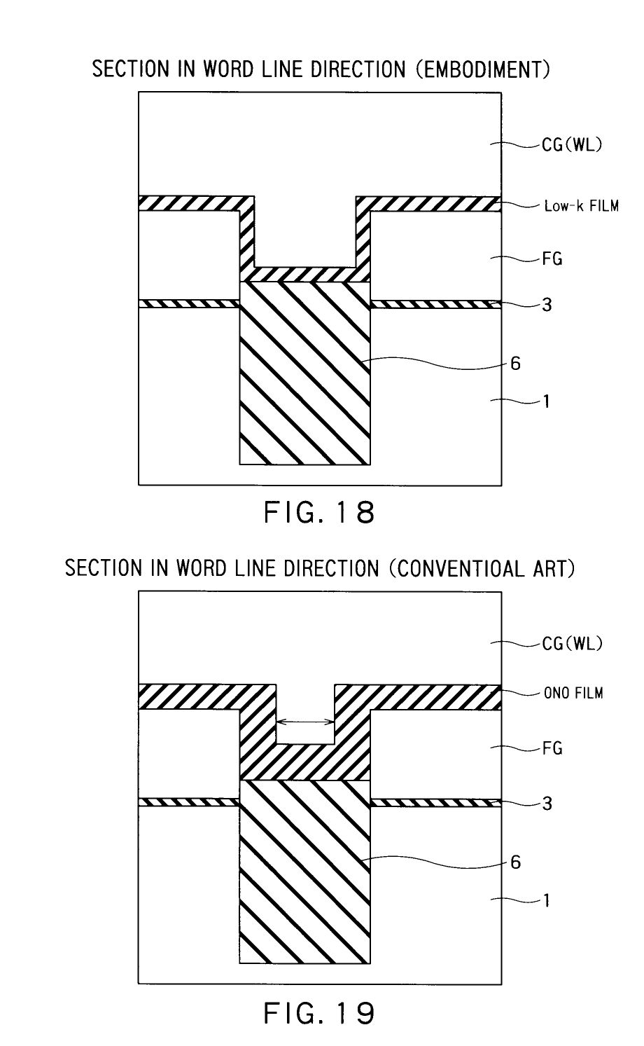

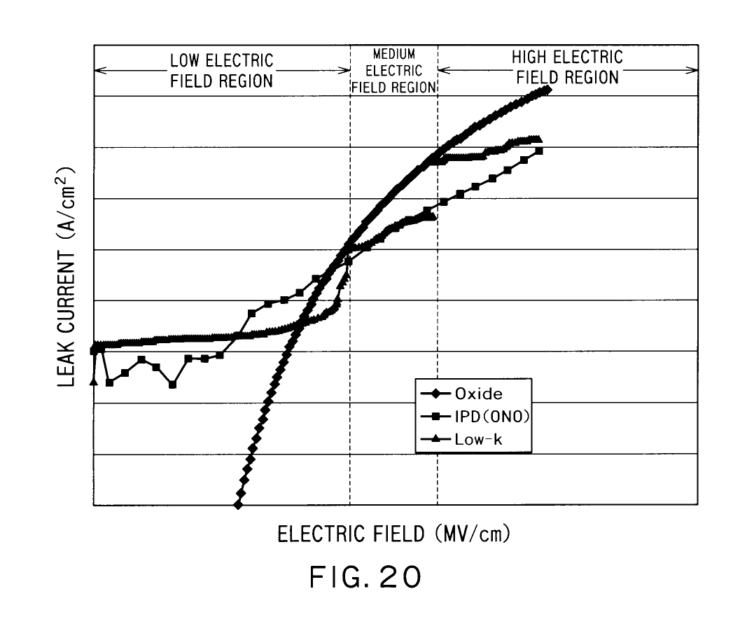

FIG. 18 is a sectional view showing a section of the NAND flash memory 100 according to the first embodiment taken along the word line paying attention to the space between adjacent floating gate electrodes. FIG. 19 is a sectional view showing a section of the conventional NAND flash memory taken along the word line paying attention to the space between adjacent floating gate electrodes.

In the present embodiment, the low-k film is used as the IPD film in the NAND flash memory. As a result, the IPD film between adjacent floating gate electrodes can be formed as a thin film while satisfying characteristics demanded for the memory cell. In other words, a space S1 between adjacent to a side surface of the IPD films disposed to a side surface of the floating gate electrode FG can be made wide as shown in FIG. 18. As a result, the size of the space between floating gate electrodes can be shrunk.

In the present embodiment, therefore, it becomes possible to further shrink the size of the memory cell in the NAND flash memory.

On the other hand, in the conventional art already described, a high dielectric constant film composed of, for example, three layers SiO₂—SiN—SiO₂ is used as the IPD film in the NAND flash memory. As a result, it is not possible to make the IPD film between adjacent floating gate electrodes thin while satisfying characteristics demanded for the memory cell. In other words, a space S2 between adjacent to a side surface of the IPD films disposed to a side surface of the floating gate electrode FG becomes narrow as shown in FIG. 19. Therefore, the size between floating gate electrodes cannot be shrunk.

Characteristics of leak currents of the low-k film, the ONO film and the silicon oxide film will now be described.

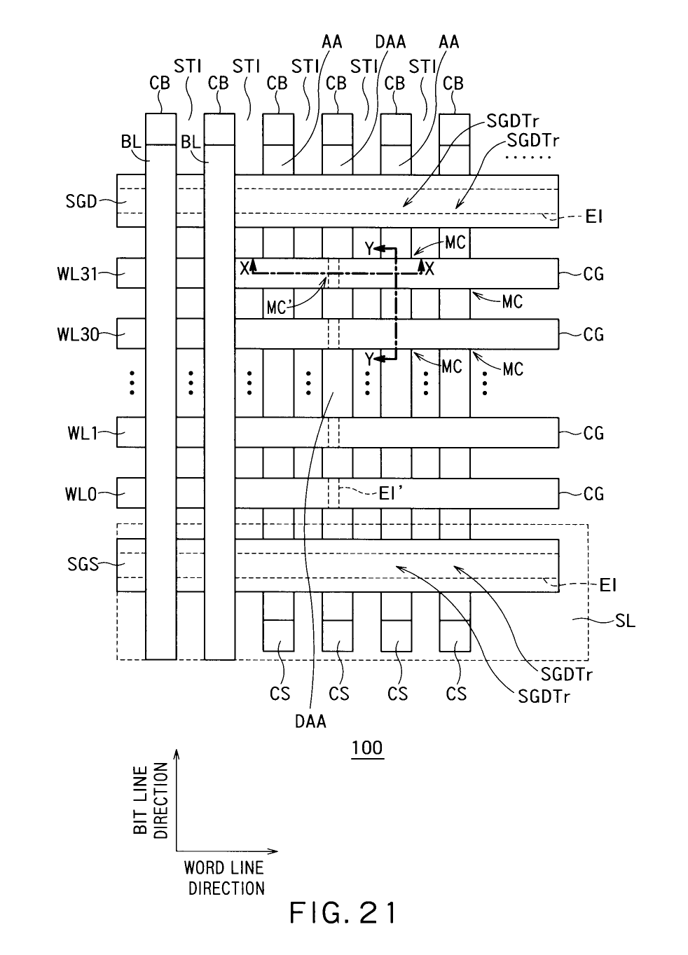

FIG. 20 is a diagram showing relations between an electric field applied to the low-k film, the ONO film and the silicon oxide film having the same film thickness and their leak currents.

In a middle electric field region where the memory cell transistor is turned on certainly regardless of the threshold voltage of the memory cell and a high electric field region where injection of charge into the floating gate electrode FG takes place, the low-k film is smaller than the silicon oxide film in leak current and has characteristics which are nearly the same as those of the ONO film as shown in FIG. 20. In this way, the low-k film can be sufficiently applied as the IPD film in the NAND flash memory. Also in the case where an air gap is used in the IPD film, insulation higher than that of the ONO film and sufficient leak characteristics are obtained, and the IPD film can be applied to the NAND flash memory in the same way.

According to the NAND flash memory in the present embodiment, the size of the memory cell can be shrunk as heretofore described.

### Second Embodiment

In the first embodiment, an example of a configuration which conducts insulation between the word line WL (control gate electrode CG) and the floating gate electrode FG by using the low-k film and its manufacturing method have been described.

In the second embodiment, an example of configuration which conducts insulation between the word line WL (control gate electrode CG) and the floating gate electrode FG by using an air gap and its manufacturing method will be described.

The configuration of the NAND flash memory in a second embodiment is the same as that of the NAND flash memory 100 according to the first embodiment shown in FIG. 1 except the point described above.

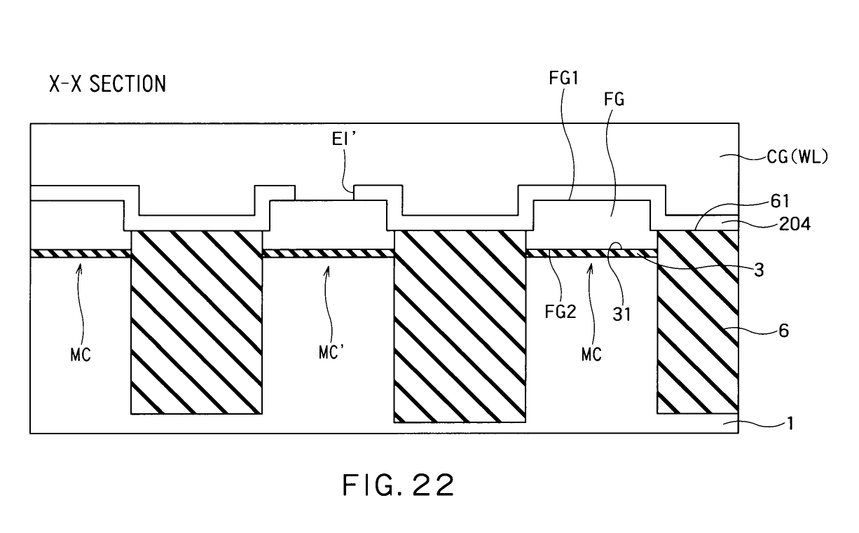

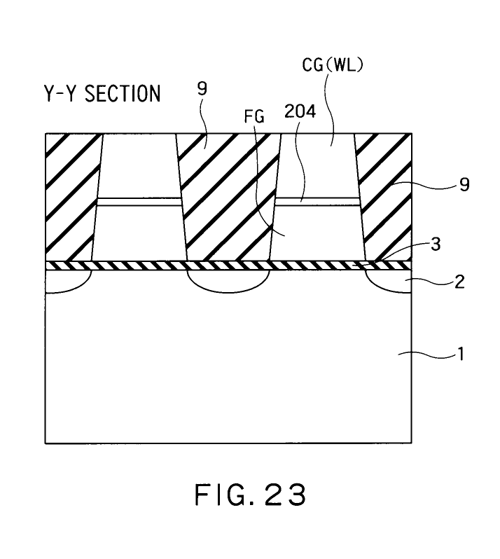

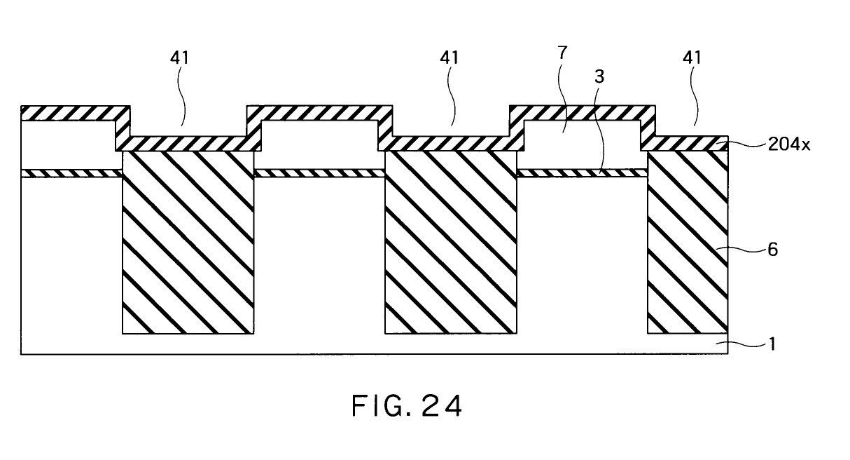

FIG. 21 is a plan view of a schematic pattern near a memory cell array of a NAND flash memory 100 according to the second embodiment which is one aspect of the present invention. FIG. 22 is a sectional view of a section of the NAND flash memory 100 shown in FIG. 21 taken along an X-X line. FIG. 23 is a sectional view of a section of the NAND flash memory 100 shown in FIG. 21 taken along a Y-Y line.

The same characters as those in the drawings for the first embodiment denote components which are like those denoted by the characters in the drawings for the first embodiment.

As shown in FIGS. 21, 22 and 23, element regions AA and element isolation regions STI which extend in the longitudinal direction in FIGS. 21, 22 and 23 are formed on a silicon substrate 1, which is a semiconductor substrate, in a memory cell region of the NAND flash memory cell 100 by a line & space pattern extending in a first direction (bit line BL direction).

In the same way as the first embodiment, the NAND flash memory cell 100 includes selection gate transistors SGDTr and SGSTr, and memory cells MC.

In addition, as shown in FIG. 21, one dummy element region DAA extending in the longitudinal direction in FIG. 21 is formed between element regions AA via the element isolation region STI, in the second embodiment. A plurality of dummy memory cells MC′ which do not function as memory cells are formed in a part in which the dummy element region DAA intersects word lines WL.

The memory cell MC includes diffusion layers 2, the gate insulation film (tunnel oxide film) 3, a floating gate electrode FG, an air gap 204, and the control gate electrode CG (word line WL).

The diffusion layers 2 are formed in regions which are included in the element region AA and located on both sides of the floating gate electrode FG.

The floating gate electrode FG takes a pillared shape formed on the element region AA via the gate insulation film 3.

The air gap 204 is formed on the top face of the floating gate electrode FG so as to extend over side faces of the floating gate electrode FG in the second direction (word line direction) perpendicular to the first direction (bit line direction). The air gap 204 is formed on the element isolating insulation film 6 as well.

The control gate electrode CG is formed on the floating gate electrode FG and between adjacent floating gate electrodes FG via the air gap 204 so as to be continuous in the second direction (word line direction) perpendicular to the first direction (bit line direction). As a result, the coupling ratio of the memory cell MC already described can be increased.

In this way, the control gate electrode CG is formed so as to extend over adjacent element regions AA (i.e., so as to stride across the element isolating insulation film 6 in the element isolation region). The air gap 204 is formed between the control gate electrode CG and the element isolating insulation film 6 as well.

The dummy memory cell MC′ includes the gate insulation film (tunnel oxide film) 3, the floating gate electrode FG, the air gap 204, and the control gate electrode CG (the word line WL). The dummy memory cell MC′ has a structure which is nearly the same as that of the memory cell MC. However, the structure of the dummy memory cell MC′ is different from that of the memory cell MC in that the floating gate electrode FG is connected to the control gate electrode CG in a part of a supporting part EI′ shown in FIG. 21.

The dummy memory cell MC′ short-circuits the floating gate electrode FG to the control gate electrode CG. As a result, the control gate CG extending in the word line WL direction is supported. The control gate CG of the memory cell MC and the control gate CG of the dummy memory cell MC′ are connected in common. In other words, since the control gate electrode CG is supported in the part of the supporting part EI′ of the dummy memory cell MC′, the control gate electrode CG is prevented from falling onto the floating gate electrode FG by its own weight. In other words, an air bridge is formed around the supporting part EI′. The supporting part EI′ is made of the same material as that of the control gate electrode CG.

The floating gate electrode FG takes a convex shape tapered upward. Owing to this structure, the space between adjacent floating gate electrodes FG can be widened. As a result, the size shrinking of the memory cell can be further attempted.

The remaining configuration of the NAND flash memory according to the second embodiment other than the above-described points is the same as that of the NAND flash memory according to the first embodiment.

A manufacturing method of the NAND flash memory 100 according to the second embodiment having the configuration described heretofore will now be described.

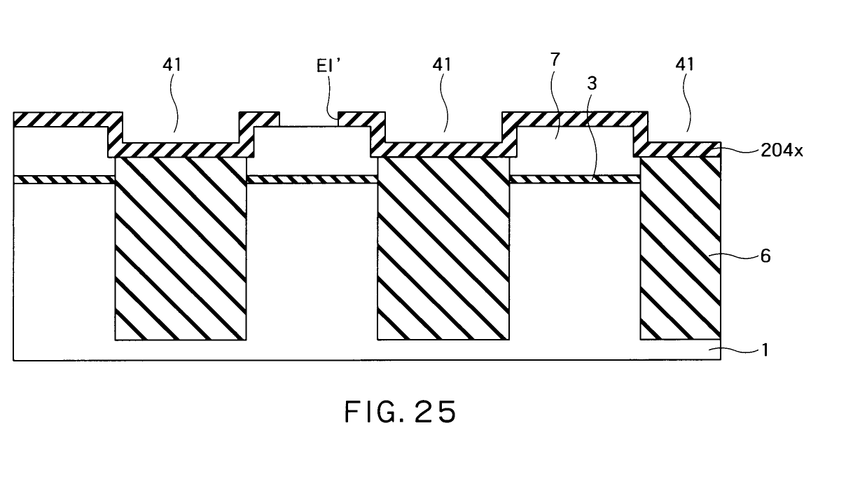

FIGS. 24 to 30 are sectional views showing the section of the memory cell array taken along an X-X line in processes of the manufacturing method of the NAND flash memory according to the second embodiment shown in FIG. 1.

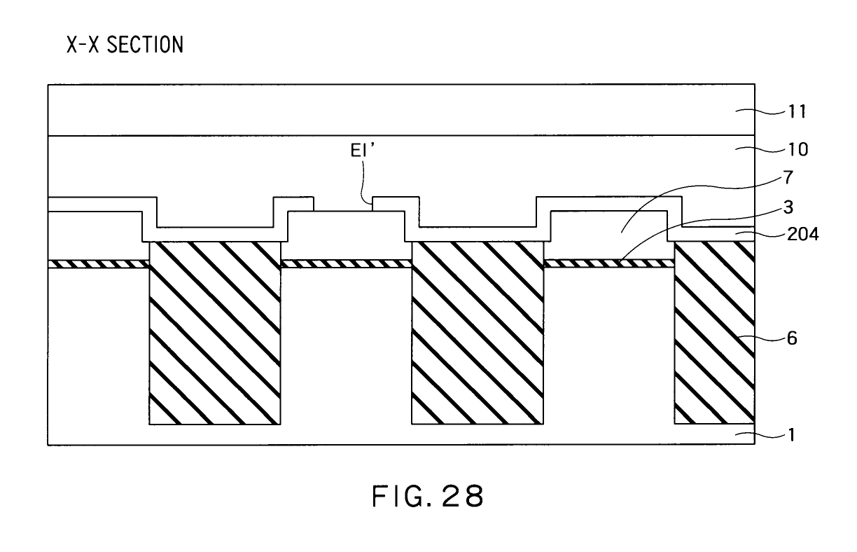

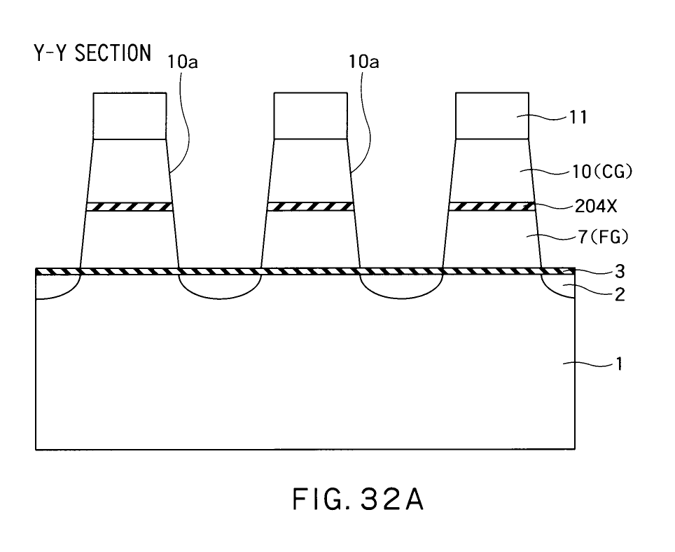

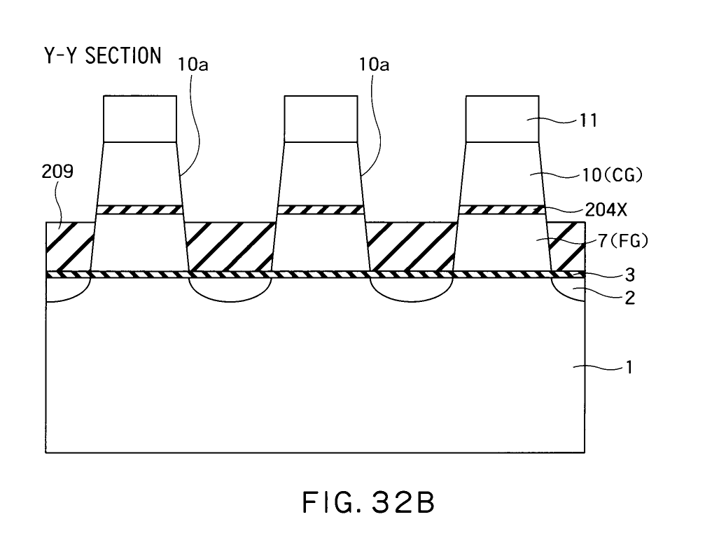

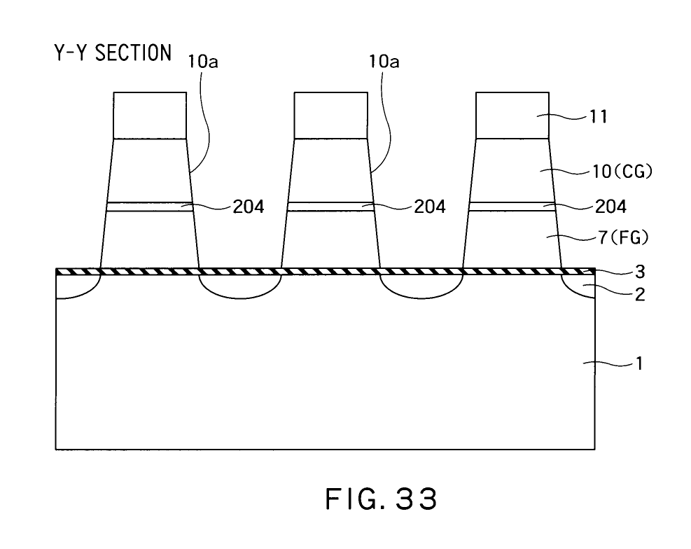

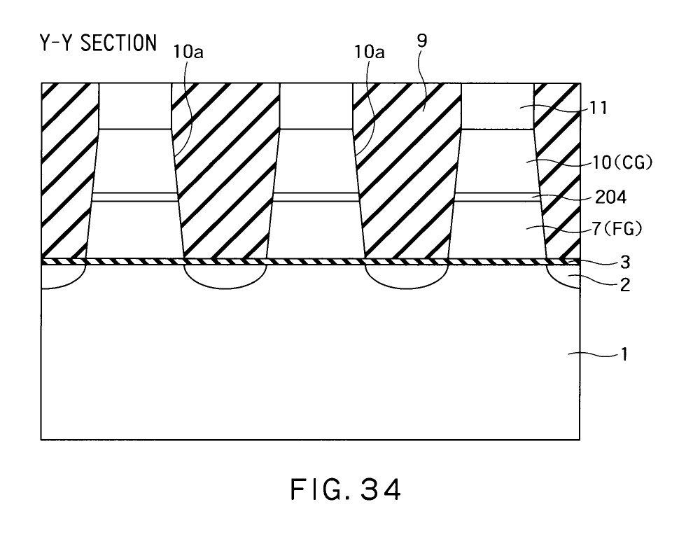

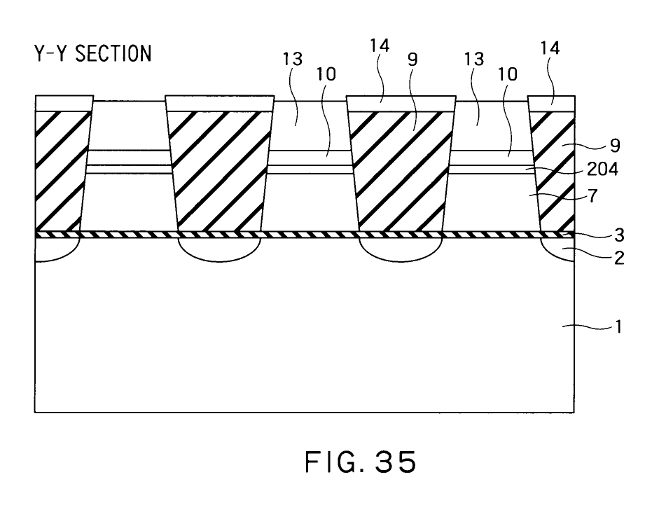

FIG. 31 is a sectional view showing a section of the memory cell array taken along a Y-Y line in the same process as that in FIG. 27 in the manufacturing method of the NAND flash memory 100 shown in FIG. 1. FIG. 32A is a sectional view showing a section of the memory cell array taken along a Y-Y line in a process subsequent to that shown in FIG. 31 in the manufacturing method of the NAND flash memory 100 shown in FIG. 1. FIG. 32B is a sectional view showing a section of the memory cell array taken along a Y-Y line in a process subsequent to that shown in FIG. 32A in the manufacturing method of the NAND flash memory 100 shown in FIG. 1. FIG. 33 is a sectional view showing a section of the memory cell array taken along a Y-Y line in a process subsequent to that shown in FIG. 32B in the manufacturing method of the NAND flash memory 100 shown in FIG. 1. FIG. 34 is a sectional view showing a section of the memory cell array taken along a Y-Y line in a process subsequent to that shown in FIG. 33 in the manufacturing method of the NAND flash memory 100 shown in FIG. 1. FIG. 35 is a sectional view showing a section of the memory cell array taken along a Y-Y line in a process subsequent to that shown in FIG. 34 in the manufacturing method of the NAND flash memory 100 shown in FIG. 1.

In the manufacturing method for the semiconductor device according to the present embodiment, processes as far as the process shown in FIG. 7 and described in the first embodiment are conducted in the same way.

The element isolating insulation film 6, the gate insulation film 3 and the polysilicon 7 are formed on the silicon substrate 1 by processes similar to those as far as the process shown in FIG. 7 and described in the first embodiment (FIG. 7).

Then, a sacrificing SiN film 204x which is a nitride film (SiN film) serving as a sacrificing film is deposited on the silicon substrate 1 so as to have a thickness of, for example, 5 nm. As a result, the sacrificing SiN film 204x is formed on the surface of the polysilicon film 7 (the floating gate electrode FG) and the surface of the element isolating insulation film 6. An exposed part of the polysilicon film 7 is eroded by the sacrificing SiN film 204x in this process. As a result, the polysilicon film 7 takes a thin convex shape in its upper part (FIG. 24). In other words, in the section in the word line direction, the polysilicon film 7 takes a shape so as to become thick in a part contiguous to the element isolating insulation film 6 and become fine in a part located above the element isolating insulation film 6 of the polysilicon film 7.

As a result, the space between adjacent floating gate electrodes FG is filled with the sacrificing SiN film 204x by approximately 10 nm.

The sacrificing SiN film 204x is made thinner in physical thickness than the high dielectric constant film used in the conventional NAND flash memory and already described.

In this process, therefore, a space 41 between the floating gate electrodes FG adjacent in the word line direction in which the sacrificing SiN film 204x is formed can be made wider as compared with the conventional art. In addition, the space 41 between the floating gate electrodes FG can be made further wider by providing the polysilicon film 7 with a convex shape.

A polysilicon is deposited on the sacrificing SiN film 204x and in the space 41 between the adjacent floating gate electrodes FG having the sacrificing SiN film 204x formed therein, so as to have a thickness of, for example, 120 nm.

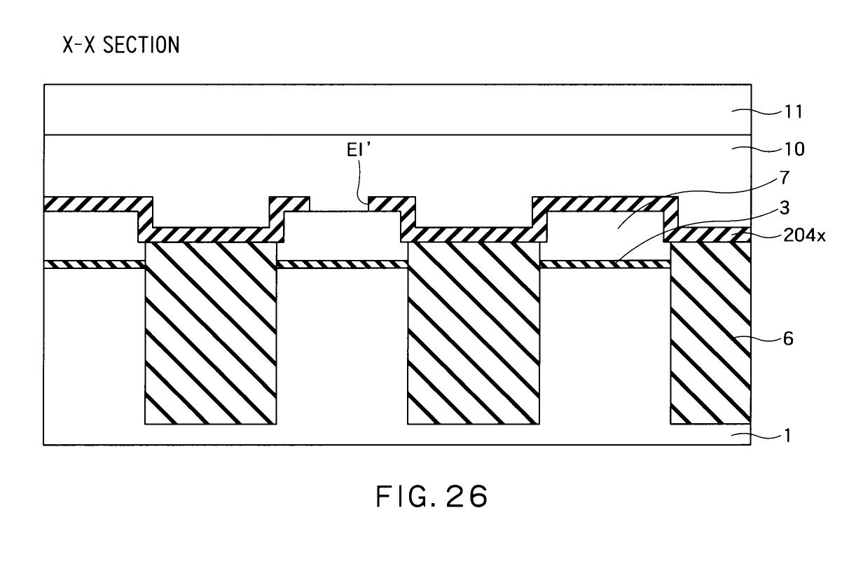

In a part in which the dummy memory cell MC′ is formed, a part of the sacrificing SiN film 204x (a part corresponding to the supporting part EI′ shown in FIG. 21) is removed. The supporting part EI′ can be formed concurrently with a connection part EI between the floating gate electrode FG and the control gate electrode CG to be formed in the selection gate electrodes SGD and SGS. As a result, the process will not be repeated. The supporting part EI′ may be formed after a part of the control gate electrode CG is deposited as a protection film (FIG. 25).

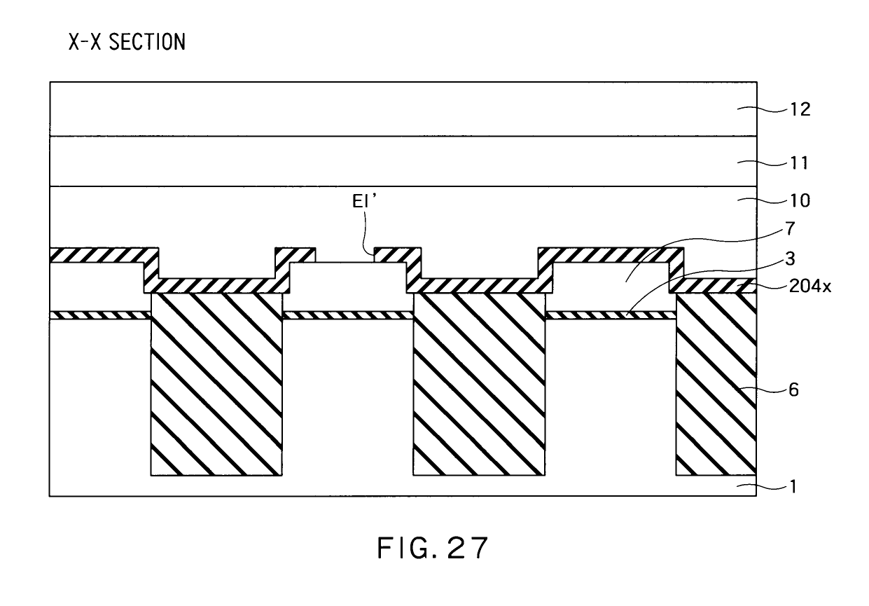

A polysilicon film 10 which becomes the control gate electrode CG is formed on the surface of the sacrificing film 204x. The supporting part EI′ is also embedded in the polysilicon film 10 in this process. In addition, a SiN film 11 which becomes a stopper film for the CMP later is deposited on the polysilicon film 10 so as to have a thickness of, for example, approximately 100 nm (FIG. 26). The SiN film 11, the polysilicon film 10, the sacrificing SiN film 204x, and the polysilicon film 7 are etched and selectively removed by using a resist pattern 12 for forming the control gate electrode CG as a mask and using the RIE method (FIGS. 27 and 31). As a result, the control gate electrode CG is formed, and a trench 10a which extends in the word line direction and which links to the silicon substrate 1 is formed.

After the remaining resist pattern 12 is removed, an HTO film (not illustrated) having a thickness of, for example, approximately 3 nm is deposited on the whole face of the silicon substrate 1 as a silicon oxide film. As a result, exposed surfaces of the floating gate electrode FG and the control gate electrode CG are covered by the silicon oxide film.

As impurities, for example, ions such as As are implanted into the silicon substrate 1 via the gate insulation film 3. In addition, the impurities are activated by using the RTA method or the like. As a result, the diffusion layers 2 are formed in the silicon substrate 1 (FIG. 32A).

An NSG (Non Doped Silicate Glass) 209 is deposited on the whole face of the silicon substrate 1. The NSG 209 is planarized until the surface of the SiN film 11 is exposed. The NSG 209 is etched back by using the RIE method. In addition, the silicon substrate 1 is subject to cleaning processing. As a result, side faces of the sacrificing SiN film 204x are exposed (FIG. 32B).

The sacrificing SiN film 204x is selectively removed by a chemical such as, for example, H₃PO₄. As a result, an air gap 204 for insulation between the floating gate electrode FG and the control gate electrode CG is formed (FIG. 33). Since the control gate electrode CG is supported by the supporting part EI′, the control gate electrode CG is prevented from falling onto the floating gate electrode FG by its own weight.

A SiO₂ film which becomes an interlayer insulation film 9 is deposited between the control gate electrodes CG by using, for example, the APCVD (Atmospheric Pressure Chemical Vapor Deposition) method which is low in coverage, or the like.

A SiN film may be deposited on the surfaces of the floating gate electrode FG and the control gate electrode CG so as to have a thickness of approximately 1 nm by using the ALD (Atomic Layer Deposition) method or the like in order to protect polysilicon surfaces of the floating gate electrode FG and the control gate electrode CG.

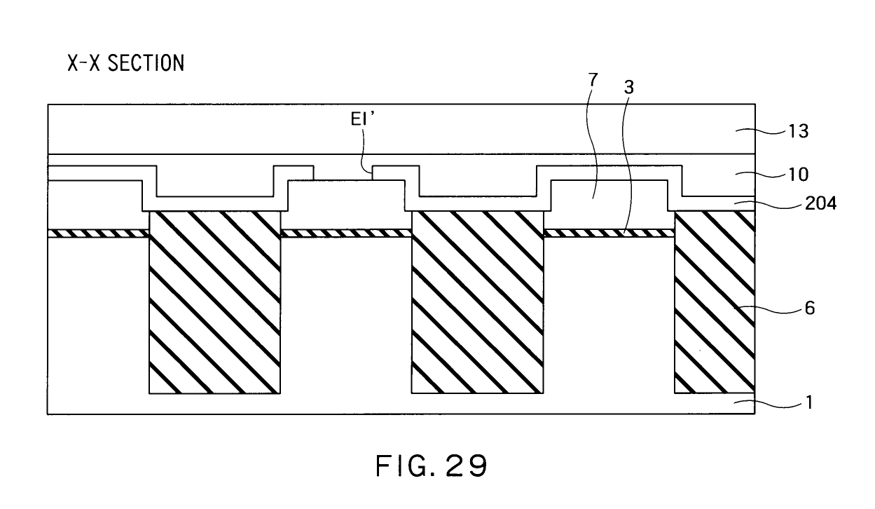

Then, the SiO₂ film is planarized by using the CMP method until the SiN film 11 is exposed (FIGS. 28 and 34).

As a result, an interlayer insulation film 9 (FIG. 23) which conducts insulation between the floating gate electrodes FG adjacent in the bit line direction (Y-Y direction) and between control gate electrodes CG adjacent in the bit line direction (Y-Y direction) is formed in the trench 10a.

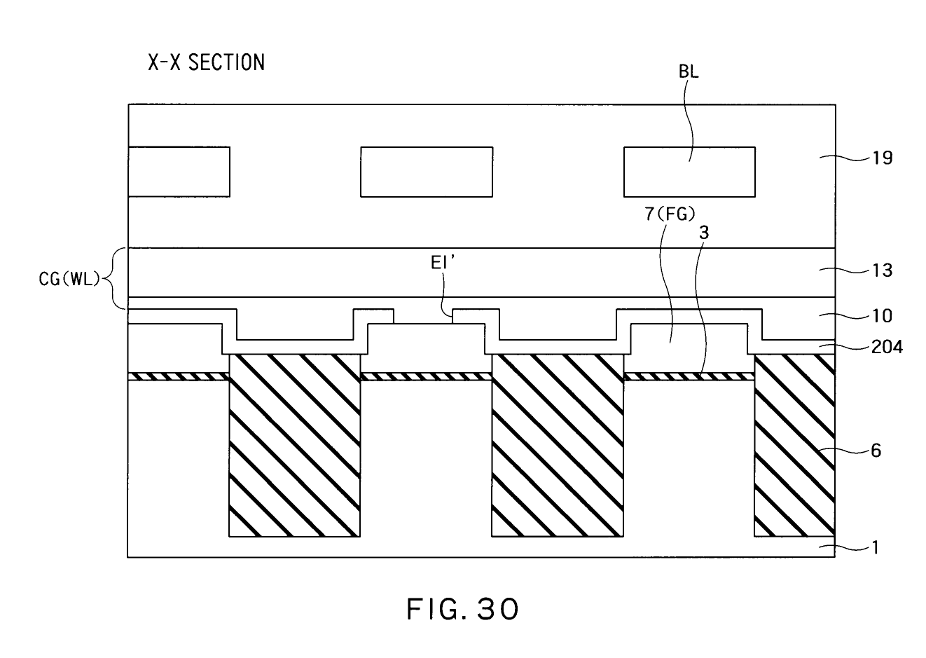

The exposed SiN film 11 is selectively removed by using, for example, the RIE method in the same way as the first embodiment. For example, a Co film 14 is deposited on the polysilicon film 10 and the interlayer insulation film 9. An upper part of the polysilicon film 10 is silicided by heat treatment required to form silicide. In other words, a silicide layer 13 is formed on the polysilicon film 10 (FIGS. 29 and 35). As a result, the control gate electrode CG is lowered in resistance. Then, the Co film 14 which dose not react is removed.

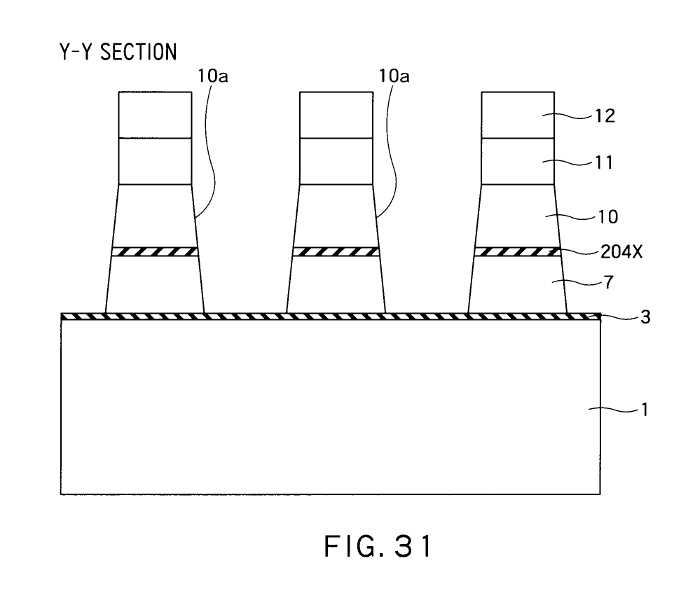

An interconnections such as an interlayer insulation film 19 and BL lines are formed on the silicon substrate 1 by a typical manufacturing process of the NAND flash memory (FIG. 30) in the same way as the first embodiment. As a result, the NAND flash memory 100 shown in FIGS. 21, 22 and 23 is completed.

In the second embodiment, the air gap is thus used as the IPD film in the NAND flash memory. As a result, a region corresponding to the IPD film between adjacent floating gate electrodes can be made narrow while satisfying characteristics demanded for the memory cell. In other words, a space S1 can be made wide as shown in FIG. 18. As a result, the size of the space between floating gate electrodes can be shrunk.

As already described, the air gap has a high insulation property and implements sufficient leak characteristics, and the air gap can be applied to the NAND flash memory in the same way.

According to the NAND flash memory in the present embodiment, the size of the memory cell can be shrunk in the same way as the first embodiment, as heretofore described.

What is claimed is:

1. A NAND flash memory comprising:
a plurality of element regions and a plurality of element isolation regions being formed in a semiconductor substrate by a line and space pattern extending in a first direction, the first element region being included in the element regions;
a first selection gate transistor formed on an one of the plurality of the first element region and connected to a bit line at one end thereof,
a second selection gate transistor formed on the one of the plurality of the first element region of the semiconductor substrate and connected to a source line at one end thereof; and
a plurality of memory cells formed on the one of the plurality of the first element region of the semiconductor substrate and connected in series between the one end of the first selection gate transistor and the one end of the second selection gate transistor,
wherein each of the memory cells comprises:
a floating gate electrode formed on the one of the plurality of the first element region via a gate insulation film;
diffusion layers formed in regions located on both sides of the floating gate electrode in the one of the plurality of the first element region;
an IPD film formed on a top face of the floating gate electrode so as to extend over side faces of the floating gate electrode in a second direction perpendicular to the first direction; and
a control gate electrode formed on the floating gate electrode and between adjacent floating gate electrodes via the IPD film so as to be continuous in the second direction,
wherein the IPD film is a low-k film.

2. The NAND flash memory according to claim 1, wherein the low-k film is each of a porous SiO₂ film or a SiCOH film.

3. The NAND flash memory according to claim 1, wherein top faces of element isolating insulation films in the element isolation regions are set so as to be higher in position than a top face of the gate insulation film.

4. The NAND flash memory according to claim 2, wherein top faces of element isolating insulation films in the plurality of the element isolation regions are set so as to be higher in position than a top face of the gate insulation film.

5. The NAND flash memory according to claim 1, wherein the floating gate electrode and the control gate electrode are composed of polysilicon.

6. A NAND flash memory comprising:
a plurality of element regions and a plurality of element isolation regions being formed in a semiconductor substrate by a line and space pattern extending in a first direction, the first element region being included in the element regions;
a first selection gate transistor formed on an one of the plurality of the first element region and connected to a bit line at one end thereof,
a second selection gate transistor formed on the one of the plurality of the first element region of the semiconductor substrate and connected to a source line at one end thereof; and
a plurality of memory cells formed on the one of the plurality of the first element region of the semiconductor substrate and connected in series between the one end of the first selection gate transistor and the one end of the second selection gate transistor,
wherein each of the memory cells comprises:
a floating gate electrode formed on the plurality of the first element region via a gate insulation film;
diffusion layers formed in regions located on both sides of the floating gate electrode in the plurality of the first element region;
an air gap formed on a top face of the floating gate electrode so as to extend over side faces of the floating gate electrode in a second direction perpendicular to the first direction; and
a control gate electrode formed on the floating gate electrode and between adjacent floating gate electrodes via the air gap so as to be continuous in the second direction.

7. The NAND flash memory according to claim 6, wherein top faces of element isolating insulation films in the plurality of the element isolation regions are set so as to be higher in position than a top face of the gate insulation film.

8. The NAND flash memory according to claim 6, wherein the floating gate electrode and the control gate electrode are composed of polysilicon.

9. The NAND flash memory according to claim 6, wherein one of the plurality of the element regions is a dummy element region,
the NAND flash memory further comprises a dummy memory cell is formed on the dummy element region,
the dummy memory cell comprises the floating gate electrode, the control gate electrode, and a supporting part that connects the floating gate electrode and the control gate electrode, and
the control gate electrode of the memory cell is connected with the control gate electrode of the dummy memory cell.

10. A NAND flash memory manufacturing method comprising:
forming a gate insulation film on a semiconductor substrate;
forming a first conductor film on the gate insulation film;
etching the gate insulation film, the first conductor film and the semiconductor substrate, and thereby forming a first trench extending in a first direction;
forming an element isolating insulation film in the first trench so as to cause a position of a top face of the element isolating insulation film to become lower than a position of a top face of the first conductor film and become higher than a position of a bottom face of the first conductor film;
depositing an insulation film on the first conductor film and the element isolating insulation film;
depositing a second conductor film on the insulation film;
etching the second conductor film, the insulation film and the first conductor film, and thereby forming a second trench extending in a second direction perpendicular to the first direction and linking to the semiconductor substrate;
removing the insulation film; and
forming an interlayer insulation film in the second trench.

11. The NAND flash memory manufacturing method according to claim 10, wherein
after depositing an insulation film, a supporting part is formed by removing a part of the insulation film and depositing the second conductor film in the removed part.

12. The NAND flash memory manufacturing method according to claim 10, wherein
the insulation film is a SiN film, and
the insulation film is removed by using a H₃PO₄ solution.

13. The NAND flash memory manufacturing method according to claim 10, wherein
after forming the second trench, the insulation film is exposed by depositing a second interlayer insulation film in the second trench and etching back the second interlayer insulation film.

14. The NAND flash memory manufacturing method according to claim 13, wherein the insulation film is a SiN film, and the second interlayer insulation film is NSG.
